(19) United States
(12) Patent Application Publication
(10) Pub. No.: US 2008/0310114 A1
(43) Pub. Date: Dec. 18, 2008

(54) HEAT-TRANSFER DEVICE FOR AN ELECTROMAGNETIC INTERFERENCE (EMI) SHIELD USING CONDUCTIVE BRISTLES

(75) Inventors: Ivan Pawlenko, Holland, PA (US); Larry Samson, Langhorne, PA (US)

Correspondence Address: MENDELSOHN & ASSOCIATES, P.C., 1500 JOHN F. KENNEDY BLVD., SUITE 405, PHILADELPHIA, PA, 19102, US

(73) Assignee: LUCENT TECHNOLOGIES INC., Murray Hill, NJ (US)

(21) Appl. No.: 11/764,667

(22) Filed: Jun. 18, 2007

(51) Int. Cl. H05K 7/20; H05K 9/00

(52) U.S. Cl. 361/704; 361/818

(57) ABSTRACT

In one embodiment, an apparatus for electronic equipment has a bristle pad having an anchor end and a free end, wherein the bristle pad has a plurality of flexible bristles each having an anchor end corresponding to the anchor end of the bristle pad and a free end corresponding to the free end of the bristle pad. The bristle pad is adapted to be placed between an electronic component and an electromagnetic interference (EMI) shield for the electronic component, wherein the EMI shield provides EMI shielding for the electronic component. The plurality of flexible bristles are adapted to provide a conductive thermal path between the electronic component and the EMI shield, and one or more of the flexible bristles are adapted to flex when the RF shield is attached to a circuit pack.

### BACKGROUND OF THE INVENTION

1. Field of the Invention

The present invention relates to circuit packs having components using electromagnetic interference (EMI) shielding and heat-dissipation enhancement.

2. Description of the Related Art

A circuit pack generally comprises a plurality of variously interconnected and physically proximate electronic components that are generally soldered to a base circuit board. As used herein, “circuit pack” refers to any configuration of one or more electronic components connected on a common substrate. These electronic components may include integrated circuits, analog devices, digital devices, and radio-frequency (RF) components. One or more electronic components may require an electromagnetic interference (EMI) shield, also referred to as an RF shield or a can. An EMI shield is useful for reducing electromagnetic interference caused by the shielded component and/or that can affect the shielded component. Thus, an EMI shield can be used to protect other components from EMI generated by the shielded component, and an EMI shield can be used to protect a component from externally-generated EMI. A simple EMI shield is typically made in the shape of an open-bottomed metal enclosure placed over the shielded component and attached to the base circuit board.

As would be appreciated by one of ordinary skill in the art, there are many ways to form an EMI shield enclosure. For example, the EMI shield can be a unitary piece attached to a circuit board, as disclosed in U.S. Pat. No. 5,530,202 to Dais et al., incorporated herein by reference in its entirety. The EMI shield can also be formed by attaching a lid to a walled enclosure that was previously attached to a circuit board, as disclosed in U.S. Pat. Nos. 7,095,624 B2 to Daoud et al. and 7,113,410 B2 to Pawlenko et al., incorporated herein by reference in their entirety.

The shielded component may get hot in operation and consequently may benefit from heat-dissipation enhancement to prevent overheating of the shielded component. The phrase “heat-dissipation enhancement,” as used herein, unless otherwise indicated, describes any means whose use increases, or is intended to increase, the heat-loss, or cooling, rate of a component. One way to cool the shielded component is with an airflow provided by a fan associated with the circuit pack. Circuit packs typically use one or more fans to provide cooling air for circuit pack components. In order for the cooling air to reach the shielded component, the EMI shield may be perforated. EMI-shield perforations whose diameters are at least about an order of magnitude smaller than the wavelengths of the EMI of concern generally do not degrade the shielding performance of the EMI shield.

FIG. 1 shows prior-art EMI shield 102 on a partial circuit board 101. EMI shield 102 is perforated to allow cooling air to reach a shielded component (not shown). Another way to provide thermal dissipation for the shielded component is to interpose a metal coil spring connected between the shielded component and the EMI shield. The metal spring conducts heat from the shielded component to the surface of the EMI shield from where it may be more easily dissipated. The spring is useful for maintaining contact between the shielded component and the EMI shield while allowing for physical-dimension variations due to (i) component dimensional tolerances and/or (ii) temperature-related expansion and/or contraction.

FIG. 2 shows a cutaway view of exemplary prior-art heat-dissipating EMI-shielding box 200. Box 200 comprises EMI shield 201, which includes top section 202. EMI shield 201 has perforations to allow for easier circulation of air within it. Top section 202 can be a lid that is attached after the rest of EMI shield 201 is mounted onto a circuit board (not shown), or top section 202 can be an integral part of EMI shield 201, i.e., formed together with the rest of EMI shield 201 prior to mounting on a circuit board. Box 200 further comprises copper coil spring 203, which is attached to copper slug 204. Copper slug 204 is attached to top section 202, for example, with a screw (not shown). When box 200 is in place in a circuit pack, then copper coil spring 203 is in contact with a shielded component (not shown) and is therefore compressed to an extent determined by, among other factors, the length of copper coil spring 203, and the heights of the shielded component and of EMI shield 201. Heat can therefore be conductively dissipated from the shielded component via copper coil spring 203, copper slug 204, and EMI shield 201.

As the operating frequencies of components keep increasing, their operating temperatures increase and novel means of heat dissipation for EMI-shielded components may be useful.

### SUMMARY OF THE INVENTION

In one embodiment, the invention can be an apparatus comprising a bristle pad having an anchor end and a free end, wherein the bristle pad comprises a plurality of flexible bristles. The bristle pad is adapted to be placed between an electronic component and an electromagnetic interference (EMI) shield for the electronic component, wherein the EMI shield provides EMI shielding for the electronic component. The plurality of bristles are adapted to provide a conductive thermal path between the electronic component and the EMI shield, and one or more of the flexible bristles are adapted to flex when the EMI shield is attached to a circuit pack.

In another embodiment, the invention can be a method for providing a conductive thermal path between an electronic component and an electromagnetic interference (EMI) shield. The method comprises (i) placing a bristle pad between the electronic component and the EMI shield, wherein the bristle pad comprises an anchor end and a free end, the bristle pad comprises a plurality of flexible bristles, the plurality of flexible bristles provide a conductive thermal path between the electronic component and the EMI shield, and the EMI shield is adapted to provide EMI shielding for the electronic component, and (ii) attaching the EMI shield to a circuit pack, whereupon one or more of the flexible bristles flex.

In yet another embodiment, the invention can be a method for operating a circuit pack comprising an electronic component. The method comprises (i) providing electromagnetic interference (EMI) shielding for the electronic component by an EMI shield attached to the circuit pack, and (ii) conducting thermal energy between the electronic component and the EMI shield using a bristle pad, wherein the bristle pad comprises an anchor end and a free end, the bristle pad comprises a plurality of flexible bristles, the plurality of flexible bristles provide a conductive thermal path between the electronic component and the EMI shield, and one or more of the flexible bristles are adapted to flex when the EMI shield is attached to the circuit pack.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows an exemplary prior-art EMI shield on a circuit board.

FIG. 2 shows a cutaway perspective view of an exemplary prior-art EMI shield with a copper coil spring.

FIG. 3 shows a cross-sectional view of part of an exemplary circuit pack in accordance with an embodiment of the current invention.

FIG. 4 shows a perspective view of part of an exemplary circuit pack in accordance with another embodiment of the current invention, wherein the circuit pack is shown in a pre-assembled stage.

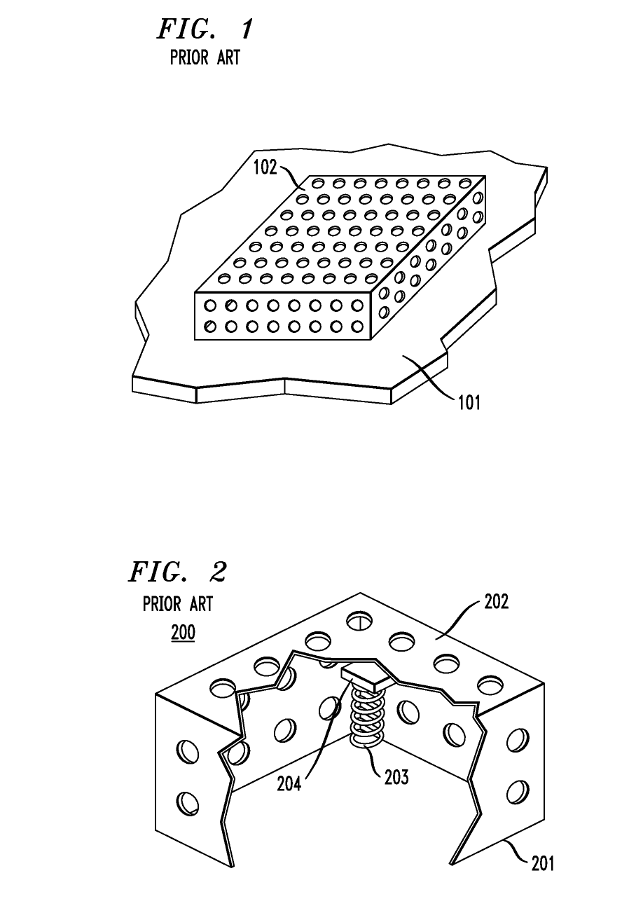

### DETAILED DESCRIPTION

Effective heat-dissipation enhancement may be provided for an EMI-shielded component by adhering a pad of metallic bristles to the shielded component, wherein the metallic bristles are long enough to stay in contact with the EMI shield while accounting for component tolerances and/or temperature-related expansion and/or contraction. Advantages of using a bristle pad may include the additional heat dissipation by the bristles themselves and compensation for variations in the gap between the EMI shield and the shielded component, and for potential minor variations in component surfaces.

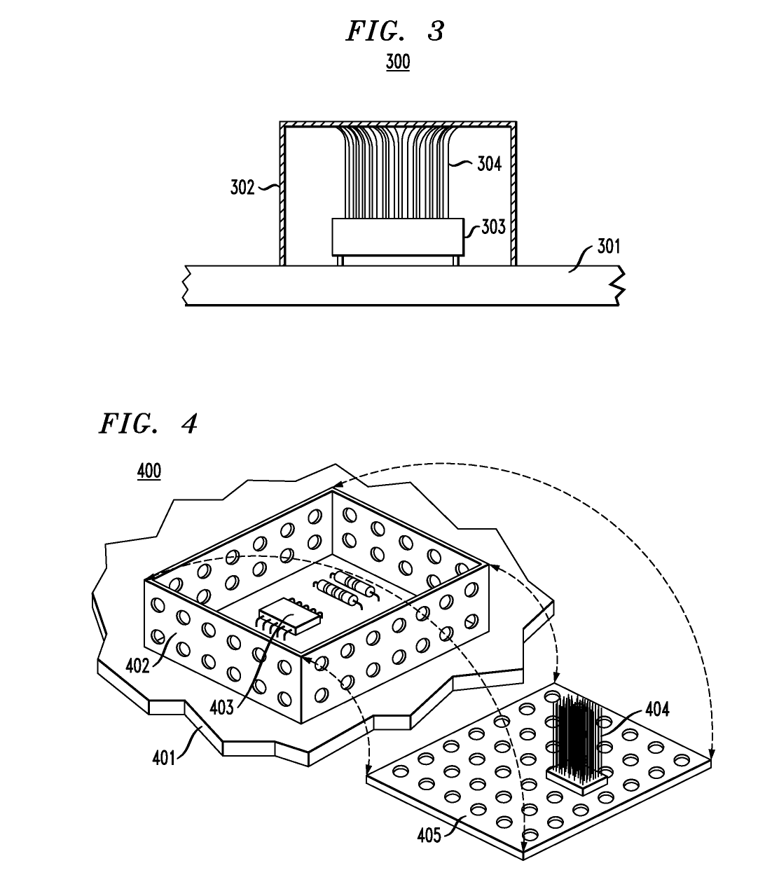

FIG. 3 shows a cross-sectional view of part of exemplary circuit pack 300 in accordance with an embodiment of the current invention. Circuit pack 300 comprises circuit board 301, various components including component 303, which requires EMI shielding, and EMI shield 302. Circuit pack 300 further comprises heat-conductive bristle pad 304, which is connected between shielded component 303 and EMI shield 302 so as to conduct thermal energy therebetween.

Component 303 may require EMI shielding from externally-generated EMI, or component 303 may require EMI shielding to protect other components from EMI that component 303 generates, or component 303 may require EMI shielding for both purposes. Component 303 can, for example, be a transformer, a coil, an inductor, an integrated circuit, an amplifier, or a transistor. EMI shield 302 may enclose additional components requiring EMI shielding (not shown), as well as additional components that do not require EMI shielding (not shown).

EMI shield 302 is made of a material, such as a metal, that is thermally conductive and provides EMI shielding. EMI shield 302 may be attached to circuit board 301 by soldering (e.g. using solder reflow), clasping, gluing, welding, adhering, bolting, using screws, or by any other suitable attachment means. EMI shield 302 may be of virtually any shape that substantially creates an enclosure when placed over shielded component 303. A typical shape is substantially an open-bottomed rectangular box. EMI shield 302 may be perforated so as to allow cooling air to flow through the space inside EMI shield 302 and cool component 303 and/or bristle pad 304. EMI shield 302 may also have additional perforations for other purposes and such perforations may be smaller or larger than the air-flow perforations and may even degrade the effectiveness of the EMI shielding.

Bristle pad 304 has an anchor end and a free end. The anchor end attaches to component 303 with heat-conducting adhesive or thermal grease while the free end contacts EMI shield 302. The free end of bristle pad 304 may also use thermal grease or heat-conductive adhesive. In one alternative embodiment, no thermal grease or adhesive is used, and instead, bristle pad 304 is held in place by other means, such as compressive pressure from component 303 and EMI shield 302. In one alternative embodiment, the anchor end attaches to the EMI shield and the free end contacts the shielded component(s).

Bristle pad 304 comprises a plurality of bristles, each bristle having an anchor end at the anchor end of bristle pad 304 and a free end at the free end of bristle pad 304. Bristle pad 304 also comprises a support structure that holds together the bristles. The support structure may be a copper slug or a thinner conductive sheet at the anchor end of bristle pad 304. Alternatively, the support structure may be of a thermal-insulating material placed towards, but not at, the anchor end of bristle pad 304. The footprint of bristle pad 304 may approximate the top-surface shape of component 303, or may have any other convenient or suitable shape. In one alternative embodiment, bristle pad 304 does not include a support structure to hold together the bristles; instead, the bristles are individually anchored at their anchor ends.

The bristles of bristle pad 304 are made from a heat-conducting and elastic material, such as copper. When freestanding, such as prior to enclosure between component 303 and EMI shield 302, the bristles of bristle pad 304 are substantially parallel to each other and are substantially similar to each other. In one alternative embodiment, the free end of bristle pad 304 is shaped so that the bristles are not substantially the same length, for example, so that bristles towards the middle of bristle pad 304 are shorter than bristles towards the periphery of bristle pad 304. Once enclosed between component 303 and EMI shield 302, the bristles, which are flexible, will flex to an extent determined by their attributes (e.g., composition, shape, length, cross-section) and the distance between component 303 and EMI shield 302. Each bristle may be a cylinder whose cross-section may be circular, oval, or other geometric curve. In one alternative embodiment, each bristle may be frustum-like with the wider end as the anchor end and the narrower end as the free end.

The free end of each bristle may be deformed or shaped for increased contact surface area with EMI shield 302 or to avoid plugging up perforations in EMI shield 302. For example, the free ends of each bristle may be flattened. The length of each bristle is sufficient to maintain thermo-conductive contact between component 303 and EMI shield 302 despite variations due to physical-dimension tolerances and thermal-related expansions and contractions. In the alternative embodiment wherein bristle pad 304 is shaped so that the bristles are not substantially the same length, some of the bristles might not maintain contact between component 303 and EMI shield 302. If, as in an alternative embodiment, bristle pad 304 is anchored to EMI shield 302, then the length of the bristles should not be so long so as to potentially damage components or electrically short leads or traces on circuit board 301. The diameter of each bristle should be small enough to allow relatively easy bending of the bristle when EMI shield 302 is placed over component 303 with bristle pad 304 in between. Typical diameters for copper-wire bristles may be in the 0.001-0.005 inch range.

FIG. 4 shows a perspective view of part of exemplary circuit pack 400 in accordance with another embodiment of the current invention, wherein circuit pack 400 is shown in a pre-assembled stage. Circuit pack 400 comprises circuit board 401, open EMI enclosure 402, shielded component 403, EMI shield lid 405, and bristle pad 404. Open EMI enclosure 402 encloses several components attached to circuit board 401, including shielded component 403. EMI shield lid 405 is shown prior to its installation atop open EMI enclosure 402 and shielded component 403. EMI shield lid 405 is shown with its bottom side up to expose bristle pad 404, the view of which would be substantially occluded after the installation of EMI shield lid 405. Open EMI enclosure 402 and EMI shield lid 405 have perforations to allow the easier circulation of air within the area of EMI enclosure 402. Bristle pad 404, which is similar to bristle pad 304 of FIG. 3, is attached to EMI shield lid 405 at the anchor end of bristle pad 404. When EMI shield lid 405 is installed atop open EMI enclosure 402 and shielded component 403, then the free end of bristle pad 404 will be in contact with the top of shielded component 403, thereby enhancing the dissipation of heat from shielded component 403.

The area, other dimensions, and location on EMI shield lid 405 of bristle pad 404 can be customized for the dimensions and location of shielded component 403. Additional bristle pads (not shown) may be attached to EMI shield lid 405 to accommodate additional shielded components within open EMI enclosure 402. In one alternative embodiment, the area of bristle pad 404 can allow for a “one size fits all” fit wherein the area of bristle pad 404 is sufficiently large to accommodate a variety of shielded components having a variety of areas, sizes, and/or locations. Thus, EMI shield lid 405 with “one size fits all” bristle pad 404 can be effectively used with multiple configurations of one or more shielded components within open EMI enclosure 402.

In one embodiment, an EMI shield, a shielded component, and a bristle pad are combined into an integrated shielded component wherein the integrated shielded component is attached as a single unit as part of a circuit pack. Such integration may provide enhanced EMI shielding as it may allow for shielding on the bottom of the component. However, such integration may also increase the complexity of the circuit pack as additional steps may be required for effective integration of the EMI shield, shielded component, and bristle pad into the integrated shielded component.

It will be understood that various changes in the details, materials, and arrangements of the parts which have been described and illustrated in order to explain the nature of this invention may be made by those skilled in the art without departing from the scope of the invention as expressed in the following claims.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Unless explicitly stated otherwise, each numerical value and range should be interpreted as being approximate as if the word “about” or “approximately” preceded the value of the value or range. As used in this application, unless otherwise explicitly indicated, the term “connected” is intended to cover both direct and indirect connections between elements.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures. Furthermore, the use of particular terms and phrases herein is for the purpose of facilitating the description of the embodiments presented and should not be regarded as limiting.

References in descriptions of alternative embodiments to particular figures or previously-described embodiments do not limit the alternatives to those particular shown or previously-described embodiments. Alternative embodiments described can generally be combined with any one or more of the other alternative embodiments shown or described.

Although the steps in the following method claims are recited in a particular sequence with corresponding labeling, unless the claim recitations otherwise imply a particular sequence for implementing some or all of those steps, those steps are not necessarily intended to be limited to being implemented in that particular sequence.

We claim:

1. An apparatus comprising a bristle pad having an anchor end and a free end, wherein:
the bristle pad comprises a plurality of flexible bristles;
the bristle pad is adapted to be placed between an electronic component and an electromagnetic interference (EMI) shield for the electronic component, wherein the EMI shield is adapted to provide EMI shielding for the electronic component;
the plurality of flexible bristles are adapted to provide a conductive thermal path between the electronic component and the EMI shield; and
one or more of the flexible bristles are adapted to flex when the EMI shield is attached to a circuit pack.

2. The apparatus of claim 1, further comprising the EMI shield.

3. The apparatus of claim 2, further comprising the electronic component.

4. The apparatus of claim 3, further comprising the circuit pack.

5. The apparatus of claim 1, wherein the flexible bristles are metallic.

6. The apparatus of claim 1, wherein the bristle pad further comprises a support structure adapted to hold together the plurality of flexible bristles.

7. The apparatus of claim 6, wherein the support structure is substantially metallic and located at the anchor end of the bristle pad.

8. The apparatus of claim 6, wherein the support structure is composed of a thermally insulating material and is located towards the anchor end of the bristle pad.

9. The apparatus of claim 1, wherein at least one of thermal grease and thermally-conductive adhesive tape is part of the conductive thermal path between the electronic component an the EMI shield.

10. The apparatus of claim 1, wherein the anchor end of the bristle pad is attached to the electronic component.

11. The apparatus of claim 1, wherein the anchor end of the bristle pad is attached to the EMI shield.

12. The apparatus of claim 1, wherein the free end of the bristle pad is shaped such that one or more of the flexible bristles are a different length than one or more other of the flexible bristles.

13. The apparatus of claim 1, wherein one or more of the flexible bristles are substantially cylindrical.

14. The apparatus of claim 13, wherein:
each of the flexible bristles has an anchor end corresponding to the anchor end of the bristle pad and a free end corresponding to the free end of the bristle pad;
the free ends of one or more of the flexible bristles are deformed for increased surface contact area with one of the EMI shield and the electronic component.

15. The apparatus of claim 1, wherein one or more of the flexible bristles are substantially frustum-like.

16. The apparatus of claim 1, wherein the EMI shield comprises an open enclosure and a lid adapted to be mounted onto the open enclosure after the open enclosure and electronic component have been mounted on the circuit pack.

17. The apparatus of claim 1, wherein the EMI shield is perforated.

18. The apparatus of claim 1, wherein:
the flexible bristles are metallic;
the bristle pad further comprises a support structure adapted to hold together the plurality of flexible bristles;
at least one of thermal grease and thermally-conductive adhesive tape is part of the conductive thermal path between the electronic component an the EMI shield;
the support structure is substantially metallic and located at the anchor end of the bristle pad;
the anchor end of the bristle pad is attached to the EMI shield;
one or more of the flexible bristles are substantially cylindrical;
the EMI shield is perforated; and
the EMI shield comprises an open enclosure and a lid adapted to be mounted onto the open enclosure after the open enclosure and electronic component have been mounted on the circuit pack.

19. A method for providing a conductive thermal path between an electronic component and an electromagnetic interference (EMI) shield, the method comprising:
placing a bristle pad between the electronic component and the EMI shield, wherein:
the bristle pad comprises an anchor end and a free end;
the bristle pad comprises a plurality of flexible bristles;
the plurality of flexible bristles provide a conductive thermal path between the electronic component and the EMI shield; and
the EMI shield is adapted to provide EMI shielding for the electronic component; and
attaching the EMI shield to a circuit pack, whereupon one or more of the flexible bristles flex.

20. A method for operating a circuit pack comprising an electronic component, the method comprising:
providing electromagnetic interference (EMI) shielding for the electronic component by an EMI shield attached to the circuit pack; and
conducting thermal energy between the electronic component and the EMI shield using a bristle pad, wherein:
the bristle pad comprises an anchor end and a free end;
the bristle pad comprises a plurality of flexible bristles;
the plurality of flexible bristles provide a conductive thermal path between the electronic component and the EMI shield; and
one or more of the flexible bristles are adapted to flex when the EMI shield is attached to the circuit pack.
